(19) United States
(12) Patent Application Publication
(10) Pub. No.: US 2024/0333259 A1
(43) Pub. Date: Oct. 3, 2024

(54) COUPLED RESONATOR FILTER TUNING CIRCUIT

(71) Applicant: Qorvo US, Inc., Greensboro, NC (US)

(72) Inventor: Nadim Khlat, Cugnaux (FR)

(21) Appl. No.: 18/611,837

(22) Filed: Mar. 21, 2024

Related U.S. Application Data
(60) Provisional application No. 63/456,608, filed on Apr. 3, 2023.

(51) Int. Cl. H03H 9/58; H03H 9/02; H03H 9/60

(52) U.S. Cl. CPC H03H 9/584; H03H 9/60; H03H 2009/02173

(57) ABSTRACT

A coupled resonator filter (CRF) tuning circuit is provided. Herein, a CRF structure includes a ferroelectric input resonator, a ferroelectric output resonator, and a ferroelectric tuning resonator coupled to the ferroelectric input resonator and the ferroelectric output resonator via a coupling layer. In embodiments disclosed herein, a tuning controller is configured to cause the coupling layer to be polarized relative to the ferroelectric input resonator or the ferroelectric output resonator. As a result, it is possible to adapt the sustainable filter bandwidth of the CRF structure based on various radio frequency (RF) filtering requirements.

### RELATED APPLICATIONS

This application claims the benefit of U.S. provisional patent application Ser. No. 63/456,608, filed on Apr. 3, 2023, the disclosure of which is hereby incorporated herein by reference in its entirety.

### FIELD OF THE DISCLOSURE

The technology of the disclosure relates generally to tuning of a coupled resonator filter (CRF) structure, such as a coupled ferroelectric resonator filter.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications.

Ferroelectric acoustic resonators, such as ferroelectric bulk acoustic resonators (FBARs), offer ultra-small size and can operate at frequencies up to tens of gigahertz. As such, ferroelectric resonators are widely used as miniaturized filters in many high-frequency devices, such as fifth generation (5G) and 5G new radio (5G-NR) communication and/or navigation devices. The operating frequency (a.k.a. series/parallel resonance frequency) of a ferroelectric acoustic resonator is typically determined by an inner structure (e.g., thickness and elastic properties) of the ferroelectric acoustic resonator. As such, it is desirable to electrically control the ferroelectric acoustic resonator to operate at a desired frequency bandwidth without changing the inner structure of the ferroelectric acoustic resonator.

### SUMMARY

Aspects disclosed in the detailed description include a coupled resonator filter (CRF) tuning circuit. Herein, a CRF structure includes a ferroelectric input resonator, a ferroelectric output resonator, and a ferroelectric tuning resonator coupled to the ferroelectric input resonator and the ferroelectric output resonator via a coupling layer. In embodiments disclosed herein, a tuning controller is configured to cause the coupling layer to be polarized relative to the ferroelectric input resonator or the ferroelectric output resonator. As a result, it is possible to adapt a sustainable filter bandwidth of the CRF structure based on various radio frequency (RF) filtering requirements.

In one aspect, a CRF tuning circuit is provided. The CRF tuning circuit includes a CRF structure. The CRF structure includes a ferroelectric input resonator and a ferroelectric output resonator that are coupled by a piezoelectric layer. The CRF structure also includes a ferroelectric tuning resonator. The ferroelectric tuning resonator is coupled to the ferroelectric input resonator and the ferroelectric output resonator via a coupling layer. The CRF tuning circuit also includes a tuning controller. The tuning controller is configured to cause the coupling layer to be polarized relative to one of the ferroelectric input resonator and the ferroelectric output resonator to thereby modify a filter bandwidth of the CRF structure.

In another aspect, a wireless device is provided. The wireless device includes a CRF tuning circuit. The CRF tuning circuit includes a CRF structure. The CRF structure includes a ferroelectric input resonator and a ferroelectric output resonator that are coupled by a piezoelectric layer. The CRF structure also includes a ferroelectric tuning resonator. The ferroelectric tuning resonator is coupled to the ferroelectric input resonator and the ferroelectric output resonator via a coupling layer. The CRF tuning circuit also includes a tuning controller. The tuning controller is configured to cause the coupling layer to be polarized relative to one of the ferroelectric input resonator and the ferroelectric output resonator to thereby modify a filter bandwidth of the CRF structure.

In another aspect, a method for tuning a CRF structure is provided. The method includes coupling a ferroelectric input resonator and a ferroelectric output resonator by a piezoelectric layer in the CRF structure. The method also includes coupling a ferroelectric tuning resonator to the ferroelectric input resonator and the ferroelectric output resonator via a coupling layer. The method also includes polarizing the coupling layer relative to one of the ferroelectric input resonator and the ferroelectric output resonator to thereby modify a filter bandwidth of the CRF structure.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary coupled resonator filter (CRF) structure that can be tuned based on various embodiments of the present disclosure;

FIG. 2 is a schematic diagram of an exemplary CRF tuning circuit configured according to one embodiment of the present disclosure to tune the CRF structure of FIG. 1;

FIG. 3 is a schematic diagram of an exemplary CRF tuning circuit configured according to another embodiment of the present disclosure to tune the CRF structure of FIG. 1;

FIG. 4 is a graphic diagram providing an exemplary illustration as to how a direct-current (DC) voltage can be used to tune the CRF structures of FIG. 1;

FIG. 5 is a schematic diagram of an exemplary communication

device wherein the CRF tuning circuits of FIGS. 2 and 3 can be provided; and

FIG. 6 is a flowchart of an exemplary process for tuning a CRF structure in FIGS. 2 and 3.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a coupled resonator filter (CRF) tuning circuit. Herein, a CRF structure includes a ferroelectric input resonator, a ferroelectric output resonator, and a ferroelectric tuning resonator coupled to the ferroelectric input resonator and the ferroelectric output resonator via a coupling layer. In embodiments disclosed herein, a tuning controller is configured to cause the coupling layer to be polarized relative to the ferroelectric input resonator or the ferroelectric output resonator. As a result, it is possible to adapt a sustainable filter bandwidth of the CRF structure based on various radio frequency (RF) filtering requirements.

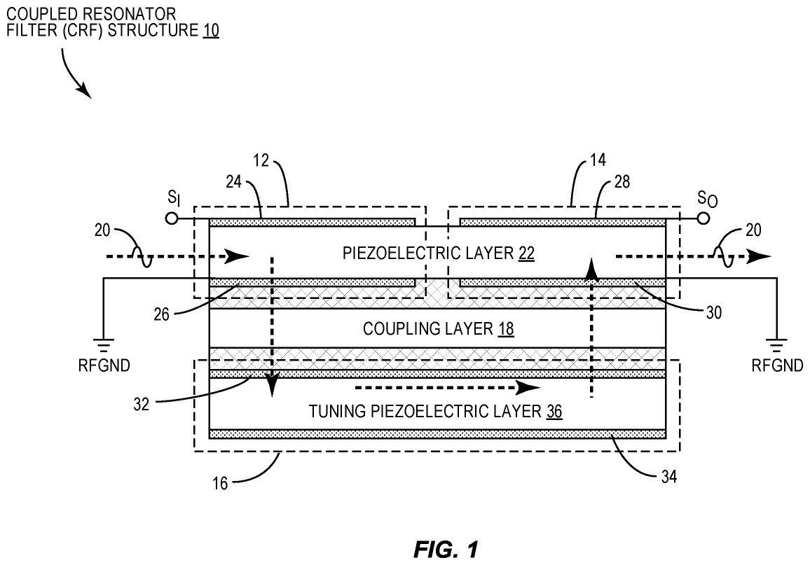

FIG. 1 is a schematic diagram of an exemplary CRF structure 10 that can be tuned based on various embodiments of the present disclosure. In a typical configuration, the CRF structure 10 includes a ferroelectric input resonator 12, a ferroelectric output resonator 14, and a ferroelectric tuning resonator 16, which is coupled to the ferroelectric input resonator 12 and the ferroelectric output resonator 14 via a coupling layer 18. The CRF structure 10 is designed to resonate in a series resonance frequency to pass a signal 20 from a signal input S_{I} to a signal output S_{O}.

In a non-limiting example, the ferroelectric input resonator 12 and the ferroelectric output resonator 14 are coupled by a piezoelectric layer 22. More specifically, the ferroelectric input resonator 12 includes a first input electrode 24 and a second input electrode 26, and the ferroelectric output resonator 14 includes a first output electrode 28 and a second output electrode 30. The first input electrode 24 and the first output electrode 28 are coupled to the signal input S_{I} and the signal output S_{O}, respectively. The second input electrode 26 and the second output electrode 30 are each coupled to an RF ground (denoted as “RFGND”). The piezoelectric layer 22 is sandwiched between the first input electrode 24 and the second input electrode 26 as well as between the first output electrode 28 and the second output electrode 30.

The coupling layer 18 is coupled to the second input electrode 26 and the second output electrode 30. The ferroelectric tuning resonator 16 includes a first tuning electrode 32, a second tuning electrode 34, and a tuning piezoelectric layer 36. The first tuning electrode 32 is coupled to the coupling layer 18, the tuning piezoelectric layer 36 is coupled to the first tuning electrode 32, and the second tuning electrode 34 is coupled to the tuning piezoelectric layer 36.

The ferroelectric tuning resonator 16 can be tuned (e.g., via a pulse voltage) to change polarization of the coupling layer 18 to thereby change a coupling factor between the ferroelectric input resonator 12 and the ferroelectric output resonator 14. Herein, the coupling factor is a measure of electrical-mechanical energy conversion efficiency that ultimately determines sustainable filter bandwidth (a.k.a. passband bandwidth) of the CRF structure 10. Specifically, the coupling factor is inversely related to the filter bandwidth of the CRF structure 10. In this regard, it is desirable to tune the CRF structure 10, either statically or dynamically, to a desired passband bandwidth for various signal filtering applications.

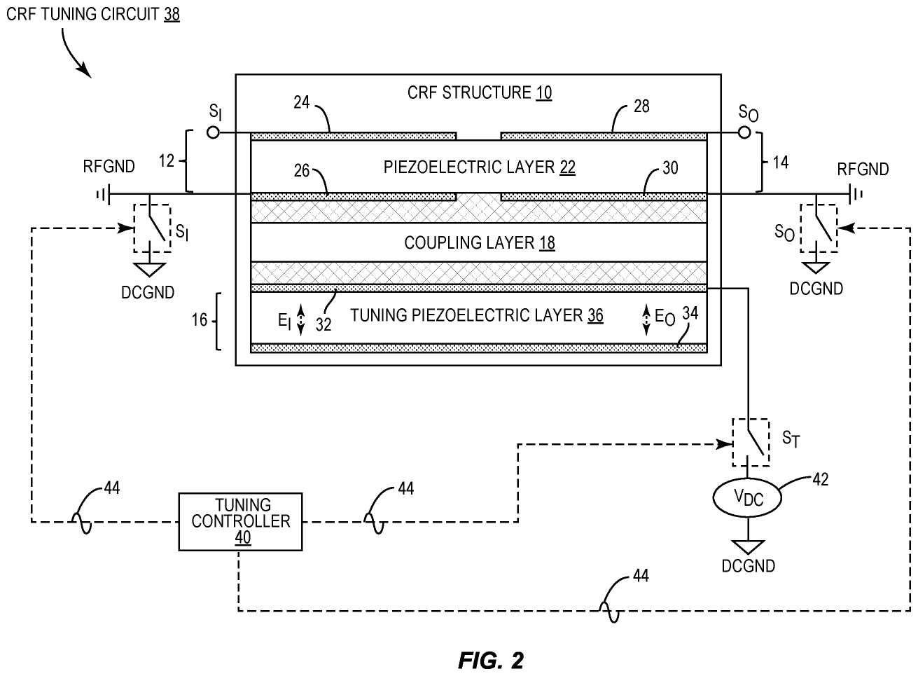

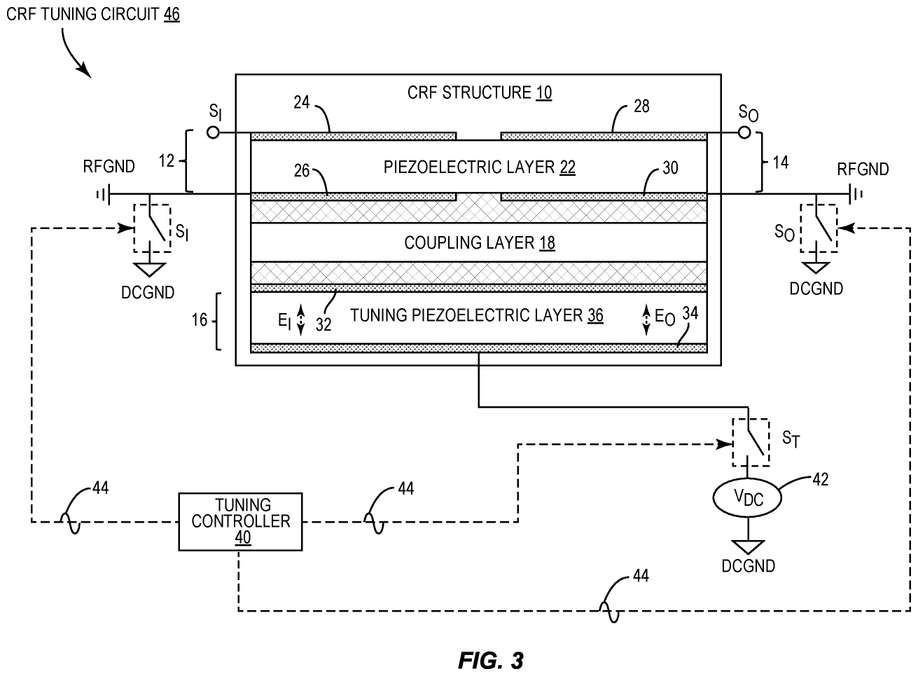

Specific embodiments for tuning the CRF structure 10 are described in detail with reference to FIGS. 2 and 3. Common elements between FIGS. 1, 2, and 3 are shown therein with common element numbers and will not be re-described herein.

FIG. 2 is a schematic diagram of an exemplary CRF tuning circuit 38 configured according to one embodiment of the present disclosure to tune the

CRF structure 10 of FIG. 1. The CRF tuning circuit 38 includes a tuning controller 40, an input switch S_{I}, an output switch S_{O}, a tuning switch ST, and a direct-current (DC) voltage source 42 that can generate a DC voltage V_{DC} (e.g., pulse voltage). In a non-limiting example, the input switch S_{I} and the output switch S_{O} can each be a silicon-on-insulator (SoI) switch or an adjustable resistor.

According to an embodiment of the present disclosure, the input switch S_{I} is coupled between the second input electrode 26 and a DC ground (denoted as “DCGND”), the output switch S_{O} is coupled between the second output electrode 30 and the DCGND, the tuning switch S_{T} is coupled to the first tuning electrode 32 (e.g., through a via), and the DC voltage source 42 is coupled between the tuning switch S_{T} and the DCGND. Notably, the DCGND can be identical to or different from the RFGND. The tuning controller 40, on the other hand, can control any one or more of the input switch S_{I}, the output switch S_{O}, and the tuning switch S_{T} via a control signal 44.

In one example, the tuning controller 40 can control the input switch S_{I}, the output switch S_{O}, and the tuning switch S_{T} to cause the coupling layer 18 to be polarized relative to the ferroelectric input resonator 12. In this regard, the tuning controller 40 is configured to concurrently close the input switch S_{I} to couple the second input electrode 26 to the DCGND, open the output switch S_{O} to decouple the second output electrode 30 from the DCGND, and close the tuning switch S_{T} to provide the DC voltage V_{DC} to the first tuning electrode 32. By closing the input switch S_{I} and the tuning switch S_{T}, the DC voltage V_{DC} will create an input electric field E_{I} that will polarize the coupling layer 18 relative to the ferroelectric input resonator 12 to thereby modify the coupling factor of the CRF structure 10.

In another example, the tuning controller 40 can control the input switch S_{I}, the output switch S_{O}, and the tuning switch S_{T} to cause the coupling layer 18 to be polarized relative to the ferroelectric output resonator 14. In this regard, the tuning controller 40 is configured to concurrently close the output switch S_{O} to couple the second output electrode 30 to the DCGND, open the input switch S_{I} to decouple the second input electrode 26 from the DCGND, and close the tuning switch S_{T} to provide the DC voltage V_{DC} to the first tuning electrode 32. By closing the output switch S_{O} and the tuning switch S_{T}, the DC voltage V_{DC} will create an output electric field E_{O} that will polarize the coupling layer 18 relative to the ferroelectric output resonator 14 to thereby modify the coupling factor of the CRF structure 10.

FIG. 3 is a schematic diagram of an exemplary CRF tuning circuit 46 configured according to another embodiment of the present disclosure to tune the CRF structure 10 of FIG. 1. Herein, the tuning switch S_{T} is instead coupled to the second tuning electrode 34.

In one example, the tuning controller 40 can control the input switch S_{I}, the output switch S_{O}, and the tuning switch S_{T} to cause the coupling layer 18 to be polarized relative to the ferroelectric input resonator 12. In this regard, the tuning controller 40 is configured to concurrently close the input switch S_{I} to couple the second input electrode 26 to the DCGND, open the output switch S_{O} to decouple the second output electrode 30 from the DCGND, and close the tuning switch S_{T} to provide the DC voltage V_{DC} to the second tuning electrode 34. By closing the input switch S_{I} and the tuning switch S_{T}, the DC voltage V_{DC} will create an input electric field E_{I} that will polarize the coupling layer 18 relative to the ferroelectric input resonator 12 to thereby modify the coupling factor of the CRF structure 10.

In another example, the tuning controller 40 can control the input switch S_{I}, the output switch S_{O}, and the tuning switch S_{T} to cause the coupling layer 18 to be polarized relative to the ferroelectric output resonator 14. In this regard, the tuning controller 40 is configured to concurrently close the output switch S_{O} to couple the second output electrode 30 to the DCGND, open the input switch S_{I} to decouple the second input electrode 26 from the DCGND, and close the tuning switch S_{T} to provide the DC voltage V_{DC} to the second tuning electrode 34. By closing the output switch S_{O} and the tuning switch S_{T}, the DC voltage V_{DC} will create an output electric field E_{O} that will polarize the coupling layer 18 relative to the ferroelectric output resonator 14 to thereby modify the coupling factor of the CRF structure 10.

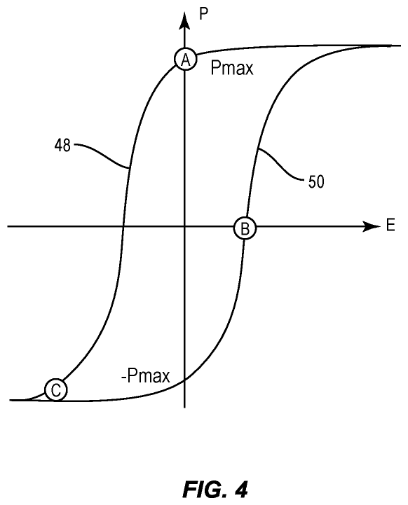

As described in FIGS. 2 and 3, the DC voltage V_{DC} can cause the coupling layer 18 to be positively or negatively polarized with respect to the ferroelectric input resonator 12 or the ferroelectric output resonator 14. FIG. 4 is a graphic diagram providing an exemplary illustration as to how the DC voltage V_{DC} can be used to tune the CRF structure 10 of FIG. 1.

Herein, the x-axis represents an electric field E (E_{I} or E_{O}) caused by the DC voltage V_{DC} in the tuning piezoelectric layer 36, and the y-axis represents a polarity of the coupling layer 18 in the CRF structure 10.

When the DC voltage V_{DC} increases, the electric field E increases from point C toward point A along an ascending curve 48. As a result, the coupling layer 18 will be positively polarized. When the DC voltage V_{DC} decreases, the electric field E decreases from point A toward point B along a descending curve 50. At point B, the electric field E will be non-existent in the tuning piezoelectric layer 36 and, as a result, the coupling layer 18 will not be polarized. When the DC voltage V_{DC} changes polarity (e.g., from positive to negative), the electric field E will change its polarity between point B and point C to thereby cause the coupling layer 18 to be negatively polarized. In other words, the tuning controller 40 can change the polarity of the coupling layer 18 by changing the polarity of the DC voltage V_{DC}.

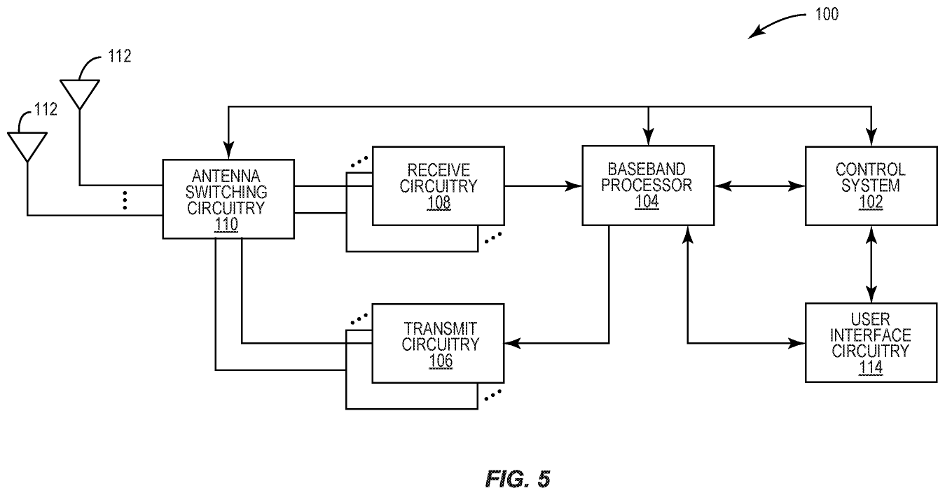

The CRF tuning circuit 38 of FIG. 2 and the CRF tuning circuit 46 of FIG. 3 can be provided in a communication device to support the embodiments described above. In this regard, FIG. 5 is a schematic diagram of an exemplary communication device 100 wherein the CRF tuning circuit 38 of FIG. 2 and the CRF tuning circuit 46 of FIG. 3 can be provided.

Herein, the communication device 100 can be any type of

communication-capable device, such as a mobile terminal, smart watch, tablet, computer, navigation device, access point, base station (e.g., eNB, gNB), and any other type of wireless communication device that supports wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal

to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data,

which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the CRF tuning circuit 38 of FIG. 2 and the CRF tuning circuit 46 of FIG. 3 may be provided in any one or more of the circuitries in the communication device 100, such as the transmit circuitry 106, the receive circuitry 108, and/or the antenna switching circuitry 110.

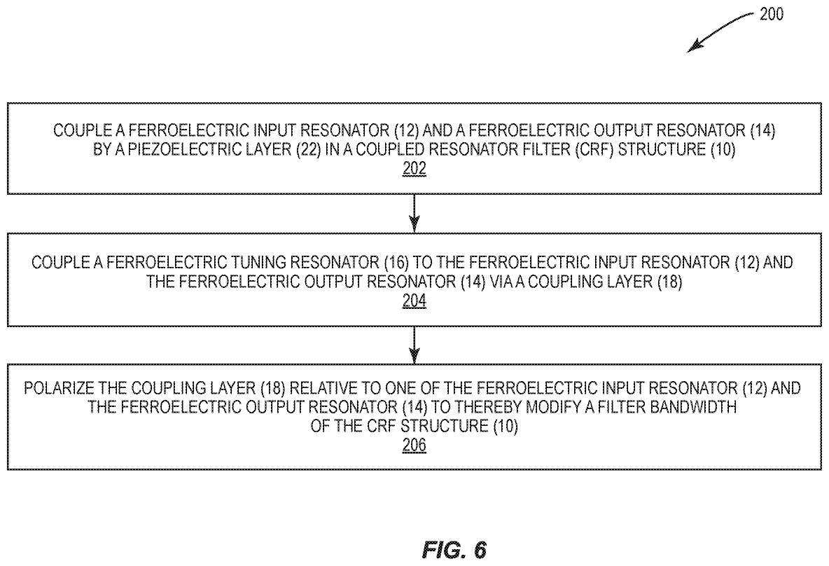

In an embodiment, the CRF structure 10 in FIGS. 2 and 3 may be tuned in accordance with a process. In this regard, FIG. 6 is a flowchart of an exemplary process 200 for tuning the CRF structure 10 in FIGS. 2 and 3.

Herein, the process 200 includes coupling the ferroelectric input resonator 12 and the ferroelectric output resonator 14 by the piezoelectric layer 22 in the CRF structure 10 (step 202). The process 200 also includes coupling the ferroelectric tuning resonator 16 to the ferroelectric input resonator 12 and the ferroelectric output resonator 14 via the coupling layer 18 (step 204). The process 200 also includes polarizing the coupling layer 18 relative to one of the ferroelectric input resonator 12 and the ferroelectric output resonator 14 to thereby modify the filter bandwidth of the CRF structure 10 (step 206).

Those skilled in the art will recognize improvements and modifications to the embodiments of the present disclosure. All such improvements and modifications are considered within the scope of the concepts disclosed herein and the claims that follow.

What is claimed is:

1. A coupled resonator filter (CRF) tuning circuit comprising:
a CRF structure comprising:
a ferroelectric input resonator and a ferroelectric output resonator coupled by a piezoelectric layer; and
a ferroelectric tuning resonator coupled to the ferroelectric input resonator and the ferroelectric output resonator via a coupling layer; and
a tuning controller configured to cause the coupling layer to be polarized relative to one of the ferroelectric input resonator and the ferroelectric output resonator to thereby modify a filter bandwidth of the CRF structure.

2. The CRF tuning circuit of claim 1, wherein:
the ferroelectric input resonator comprises:
a first input electrode and a second input electrode; and
the piezoelectric layer provided between the first input electrode and the second input electrode;
the ferroelectric output resonator comprises:
a first output electrode and a second output electrode; and
the piezoelectric layer provided between the first output electrode and the second output electrode; and
the ferroelectric tuning resonator comprises:
a first tuning electrode coupled to the coupling layer;
a tuning piezoelectric layer coupled to the first tuning electrode; and
a second tuning electrode coupled to the tuning piezoelectric layer.

3. The CRF tuning circuit of claim 2, further comprising:
an input switch coupled between the second input electrode and a direct-current (DC) ground;
an output switch coupled between the second output electrode and the DC ground;
a tuning switch coupled to the first tuning electrode; and
a DC voltage source coupled between the tuning switch and the DC ground.

4. The CRF tuning circuit of claim 3, wherein, to cause the coupling layer to be polarized relative to the ferroelectric input resonator, the tuning controller is further configured to:
close the input switch to couple the second input electrode to the DC ground;
open the output switch to decouple the second output electrode from the DC ground; and
close the tuning switch to provide the DC voltage source to the first tuning electrode.

5. The CRF tuning circuit of claim 3, wherein, to cause the coupling layer to be polarized relative to the ferroelectric output resonator, the tuning controller is further configured to:
close the output switch to couple the second output electrode to the DC ground;
open the input switch to decouple the second input electrode from the DC ground; and
close the tuning switch to provide the DC voltage source to the first tuning electrode.

6. The CRF tuning circuit of claim 2, further comprising:
an input switch coupled between the second input electrode and a direct-current (DC) ground;
an output switch coupled between the second output electrode and the DC ground;
a tuning switch coupled to the second tuning electrode; and
a DC voltage source coupled between the tuning switch and the DC ground.

7. The CRF tuning circuit of claim 6, wherein, to cause the coupling layer to be polarized relative to the ferroelectric input resonator, the tuning controller is further configured to:
close the input switch to couple the second input electrode to the DC ground;
open the output switch to decouple the second output electrode from the DC ground; and
close the tuning switch to provide the DC voltage source to the second tuning electrode.

8. The CRF tuning circuit of claim 6, wherein, to cause the coupling layer to be polarized relative to the ferroelectric output resonator, the tuning controller is further configured to:
close the output switch to couple the second output electrode to the DC ground;
open the input switch to decouple the second input electrode from the DC ground; and
close the tuning switch to provide the DC voltage source to the second tuning electrode.

9. A wireless device comprising a coupled resonator filter (CRF) tuning circuit, comprising:
a CRF structure comprising:
a ferroelectric input resonator and a ferroelectric output resonator coupled by a piezoelectric layer; and
a ferroelectric tuning resonator coupled to the ferroelectric input resonator and the ferroelectric output resonator via a coupling layer; and
a tuning controller configured to cause the coupling layer to be polarized relative to one of the ferroelectric input resonator and the ferroelectric output resonator to thereby modify a filter bandwidth of the CRF structure.

10. The wireless device of claim 9, further comprising transmit circuitry, receive circuitry, and antenna switching circuitry, wherein the CRF tuning circuit can be provided in any one or more of the transmit circuitry, the receive circuitry, and the antenna switching circuitry.

11. The wireless device of claim 9, wherein:
the ferroelectric input resonator comprises:
a first input electrode and a second input electrode; and
the piezoelectric layer provided between the first input electrode and the second input electrode;
the ferroelectric output resonator comprises:
a first output electrode and a second output electrode; and
the piezoelectric layer provided between the first output electrode and the second output electrode; and
the ferroelectric tuning resonator comprises:
a first tuning electrode coupled to the coupling layer;
a tuning piezoelectric layer coupled to the first tuning electrode; and
a second tuning electrode coupled to the tuning piezoelectric layer.

12. The wireless device of claim 11, wherein the CRF tuning circuit further comprises:
an input switch coupled between the second input electrode and a direct-current (DC) ground;
an output switch coupled between the second output electrode and the DC ground;
a tuning switch coupled to the first tuning electrode; and
a DC voltage source coupled between the tuning switch and the DC ground.

13. The wireless device of claim 12, wherein, to cause the coupling layer to be polarized relative to the ferroelectric input resonator, the tuning controller is further configured to:
close the input switch to couple the second input electrode to the DC ground;
open the output switch to decouple the second output electrode from the DC ground; and
close the tuning switch to provide the DC voltage source to the first tuning electrode.

14. The wireless device of claim 12, wherein, to cause the coupling layer to be polarized relative to the ferroelectric output resonator, the tuning controller is further configured to:
close the output switch to couple the second output electrode to the DC ground;
open the input switch to decouple the second input electrode from the DC ground; and
close the tuning switch to provide the DC voltage source to the first tuning electrode.

15. The wireless device of claim 11, wherein the CRF tuning circuit further comprises:
an input switch coupled between the second input electrode and a direct-current (DC) ground;
an output switch coupled between the second output electrode and the DC ground;
a tuning switch coupled to the second tuning electrode; and
a DC voltage source coupled between the tuning switch and the DC ground.

16. The wireless device of claim 15, wherein, to cause the coupling layer to be polarized relative to the ferroelectric input resonator, the tuning controller is further configured to:
close the input switch to couple the second input electrode to the DC ground;
open the output switch to decouple the second output electrode from the DC ground; and
close the tuning switch to provide the DC voltage source to the second tuning electrode.

17. The wireless device of claim 15, wherein, to cause the coupling layer to be polarized relative to the ferroelectric output resonator, the tuning controller is further configured to:
close the output switch to couple the second output electrode to the DC ground;
open the input switch to decouple the second input electrode from the DC ground; and
close the tuning switch to provide the DC voltage source to the second tuning electrode.

18. A method for tuning a coupled resonator filter (CRF) structure comprising:
coupling a ferroelectric input resonator and a ferroelectric output resonator by a piezoelectric layer in the CRF structure;
coupling a ferroelectric tuning resonator to the ferroelectric input resonator and the ferroelectric output resonator via a coupling layer; and
polarizing the coupling layer relative to one of the ferroelectric input resonator and the ferroelectric output resonator to thereby modify a filter bandwidth of the CRF structure.

19. The method of claim 18, further comprising polarizing the coupling layer relative to the ferroelectric input resonator.

20. The method of claim 18, further comprising polarizing the coupling layer relative to the ferroelectric output resonator.
